(19) United States
(12) Patent Application Publication
(10) Pub. No.: US 2019/0286178 A1
(43) Pub. Date: Sep. 19, 2019

(54) WIDE COMMON MODE HIGH RESOLUTION COMPARATOR

(71) Applicant: Samsung Display Co., Ltd., Yongin-si (KR)

(72) Inventors: Da Wei, Urbana, IL (US); Valentin Abramzon, Mountain View, CA (US)

(21) Appl. No.: 16/057,124

(22) Filed: Aug. 7, 2018

Related U.S. Application Data
(60) Provisional application No. 62/643,619, filed on Mar. 15, 2018.

(51) Int. Cl. G05F 1/445; H03K 3/0233; G09G 3/00

(52) U.S. Cl. CPC G05F 1/445; G09G 3/00; H03K 3/0233

(57) ABSTRACT

A comparator. The comparator includes two back-to-back inverters, a differential pair, and a first common mode compensation transistor. The differential pair has two outputs configured to receive respective series currents from, or supply respective series currents to, the back-to-back inverters. The first common mode compensation transistor is configured to supply a compensating current to, or draw a compensating current from, a first output of the two outputs of the differential pair.

### CROSS-REFERENCE TO RELATED APPLICATION(S)

The present application claims priority to and the benefit of U.S. Provisional Application No. 62/643,619, filed Mar. 15, 2018, entitled “WIDE CM HIGH SENSITIVITY STRONGARM COMPARATOR”, the entire content of which is incorporated herein by reference.

### FIELD

One or more aspects of embodiments according to the present invention relate to comparators, and more particularly to a comparator with high resolution over a broad range of common mode voltages.

### BACKGROUND

The “StrongArm” comparator, which includes a differential pair connected to two back to back inverters, may be used for low static power consumption, generating rail-to-rail output, and a high sampling bandwidth, when compared with a current mode logic counterpart. This comparator design, however, may have sensitivity that decreases significantly for input signals with high common-mode voltage.

Thus, there is a need for a comparator capable of achieving high sensitivity for input signals with high common-mode voltage.

### SUMMARY

According to an embodiment of the present disclosure, there is provided a comparator, including: a differential pair including a first transistor and a second transistor and having: a first input, connected to a control terminal of the first transistor, a second input connected to a control terminal of the second transistor, a first output connected to a main terminal of the first transistor, a second output connected to a main terminal of the second transistor, and a common node, a clock enabling transistor, connected to the common node of the differential pair, a first inverter having: an input, an output, a first series path terminal, and a second series path terminal, a second inverter having: an input, an output, a first series path terminal, and a second series path terminal, a first common mode compensation transistor, and a second common mode compensation transistor, the input of the first inverter being connected to the output of the second inverter, the input of the second inverter being connected to the output of the first inverter, the second series path terminal of the first inverter being connected to the first output of the differential pair, the second series path terminal of the second inverter being connected to the second output of the differential pair, the first common mode compensation transistor being connected between a first voltage source and the first output of the differential pair, the second common mode compensation transistor being connected between the first voltage source and the second output of the differential pair.

In some embodiments, a control terminal of the first common mode compensation transistor is connected to the second input of the differential pair.

In some embodiments, the comparator further includes a first resetting transistor connected between the first voltage source and the first output of the differential pair, a control terminal of the first resetting transistor being connected to a control terminal of the clock enabling transistor.

In some embodiments, the comparator further includes a second resetting transistor connected between the first voltage source and the output of the first inverter, a control terminal of the second resetting transistor being connected to a control terminal of the clock enabling transistor.

In some embodiments, the comparator further includes a third resetting transistor connected between the first voltage source and the second output of the differential pair, a control terminal of the third resetting transistor being connected to a control terminal of the clock enabling transistor.

In some embodiments, the comparator further includes a fourth resetting transistor connected between the first voltage source and the output of the second inverter, a control terminal of the fourth resetting transistor being connected to a control terminal of the clock enabling transistor.

In some embodiments: the first inverter includes two transistors connected in series, between the first voltage source and the first output of the differential pair, the second inverter includes two transistors connected in series, between the first voltage source and the second output of the differential pair, and the clock enabling transistor is connected between the common node of the differential pair and a second voltage source.

In some embodiments: the first voltage source is at a higher voltage than the second voltage source, the clock enabling transistor is an n-channel MOSFET, the first transistor of the differential pair is an n-channel MOSFET, the second transistor of the differential pair is an n-channel MOSFET, the first common mode compensation transistor is an n-channel MOSFET, and the second common mode compensation transistor is an n-channel MOSFET.

In some embodiments, wherein the first common mode compensation transistor has a channel width within 20% of a channel width of the first transistor of the differential pair.

In some embodiments, the second common mode compensation transistor has a channel width within 20% of a channel width of the first common mode compensation transistor.

According to an embodiment of the present disclosure, there is provided a comparator, including: two back-to-back inverters, a differential pair, having two outputs configured to receive respective series currents from, or supply respective series currents to, the back-to-back inverters, and a first common mode compensation transistor, configured to supply a compensating current to, or draw a compensating current from, a first output of the two outputs of the differential pair.

In some embodiments, the comparator further includes a second common mode compensation transistor configured to supply a compensating current to, or draw a compensating current from, a second output of the two outputs of the differential pair.

In some embodiments, the comparator further includes a clock-enabling transistor, connected to a clock signal and configured to control a total current through the differential pair.

In some embodiments, the comparator further includes a first resetting transistor configured to pull a first output, of the two outputs of the differential pair, high when the clock signal is low.

In some embodiments, the comparator further includes a second resetting transistor configured to pull an output of a first inverter, of the two back-to-back inverters, high when the clock signal is low.

In some embodiments, the first common mode compensation transistor has a channel width within 20% of a channel width of a first transistor of the differential pair.

In some embodiments, the second common mode compensation transistor has a channel width within 20% of a channel width of the first common mode compensation transistor.

According to an embodiment of the present disclosure, there is provided a display, including: a display panel and a drive and control circuit, the drive and control circuit including a plurality of integrated circuits, an integrated circuit of the plurality of integrated circuits including a comparator, the comparator including: a differential pair including a first transistor and a second transistor and having: a first input, connected to a control terminal of the first transistor, a second input connected to a control terminal of the second transistor, a first output connected to a main terminal of the first transistor, a second output connected to a main terminal of the second transistor, and a common node, a clock enabling transistor, connected to the common node of the differential pair, a first inverter having: an input, an output, a first series path terminal, and a second series path terminal, a second inverter having: an input, an output, a first series path terminal, and a second series path terminal, a first common mode compensation transistor, and a second common mode compensation transistor, the input of the first inverter being connected to the output of the second inverter, the input of the second inverter being connected to the output of the first inverter, the second series path terminal of the first inverter being connected to the first output of the differential pair, the second series path terminal of the second inverter being connected to the second output of the differential pair, the first common mode compensation transistor being connected between a first voltage source and the first output of the differential pair, the second common mode compensation transistor being connected between the first voltage source and the second output of the differential pair.

In some embodiments, a control terminal of the first common mode compensation transistor is connected to the second input of the differential pair.

In some embodiments, wherein a control terminal of the second common mode compensation transistor is connected to the first input of the differential pair.

### BRIEF DESCRIPTION OF THE DRAWINGS

These and other features and advantages of the present invention will be appreciated and understood with reference to the specification, claims, and appended drawings wherein:

FIG. 1 is a schematic diagram of a comparator;

FIG. 2A is a schematic diagram of a comparator;

FIG. 2B is a voltage graph illustrating operation of a comparator;

FIG. 3A is a schematic diagram of a comparator;

FIG. 3B is a voltage graph illustrating operation of a comparator;

FIG. 4 is a schematic diagram of a comparator, according to an embodiment of the present invention; and

FIG. 5 is a block diagram of a display, according to an embodiment of the present invention.

### DETAILED DESCRIPTION

The detailed description set forth below in connection with the appended drawings is intended as a description of exemplary embodiments of a wide common mode high resolution comparator provided in accordance with the present invention and is not intended to represent the only forms in which the present invention may be constructed or utilized. The description sets forth the features of the present invention in connection with the illustrated embodiments. It is to be understood, however, that the same or equivalent functions and structures may be accomplished by different embodiments that are also intended to be encompassed within the scope of the invention. As denoted elsewhere herein, like element numbers are intended to indicate like elements or features.

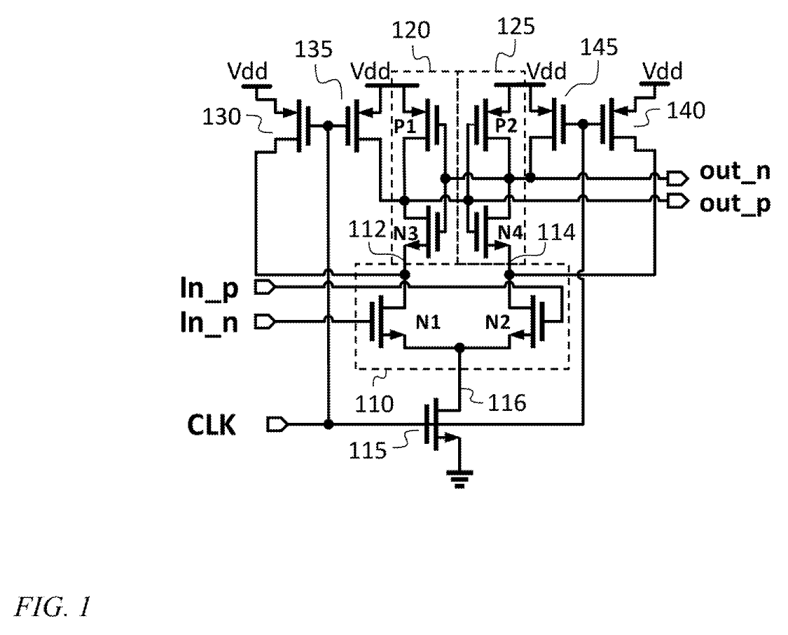

Referring to FIG. 1, in some embodiments a comparator includes a differential pair 110, a clock enabling transistor 115, a first inverter 120 (including transistors N3 and P1), and a second inverter 125 (including transistors N4 and P2).

The differential pair 110 includes two transistors, N1 and N2, connected together at a common node 116 of the differential pair. The differential pair 110 has a first input In_n, a second input In_p, a first output 112 and a second output 114. The clock enabling transistor 115 is connected between the common node 116 of the differential pair and a negative voltage source, e.g., ground. The gate of the clock enabling transistor 115 is connected to the clock input CLK of the comparator.

The first inverter 120 includes two transistors, N3 and P1. It has an output (the node connected to the drains of N3 and P1) connected to a first output out_p of the comparator, an input (the node connected to the gates of N3 and P1) connected to a second output out_n of the comparator, a first series path terminal connected to a first voltage source (e.g., a source of the positive supply voltage Vdd), and a second series path terminal connected to the first output 112 of the differential pair 110.

The second inverter 125 includes two transistors, N4 and P2. It has an input (the node connected to the gates of N4 and P2) connected to the first output out_p of the comparator, an output (the node connected to the drains of N4 and P2) connected to the second output out_n of the comparator, a first series path terminal connected to the first voltage source, and a second series path terminal connected to the second output 114 of the differential pair 110. A current flowing out of or into the second series path terminal of either of the inverters 120, 125 may be referred to as the “series current” of the inverter.

The StrongArm comparator further includes four resetting transistors: a first resetting transistor 130 connected between the first voltage source and the first output of the differential pair, a second resetting transistor 135 connected between the first voltage source and the output of the first inverter, a third resetting transistor 140 connected between the first voltage source and the second output of the differential pair, and a fourth resetting transistor 145 connected between the first voltage source and the output of the second inverter. The gate of each of the resetting transistors 130, 135, 140, 145 is connected to the clock input CLK of the comparator.

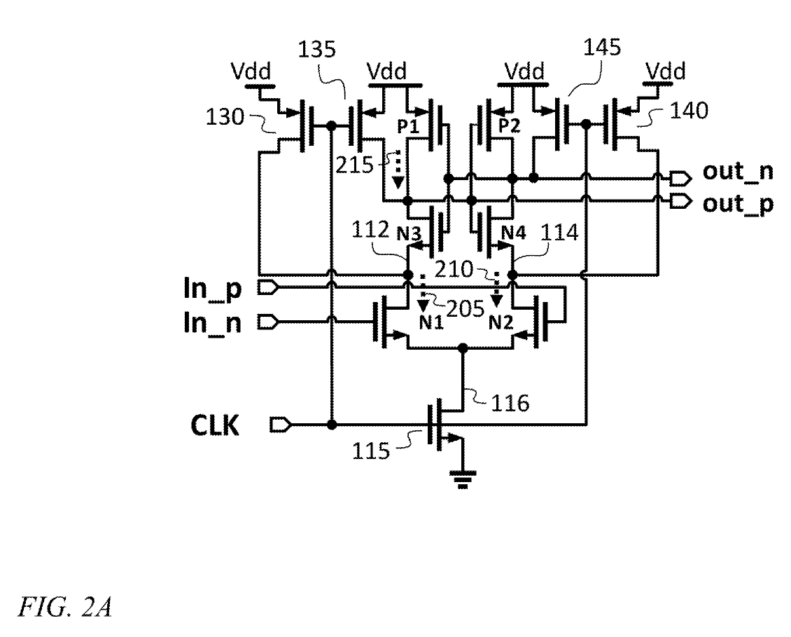

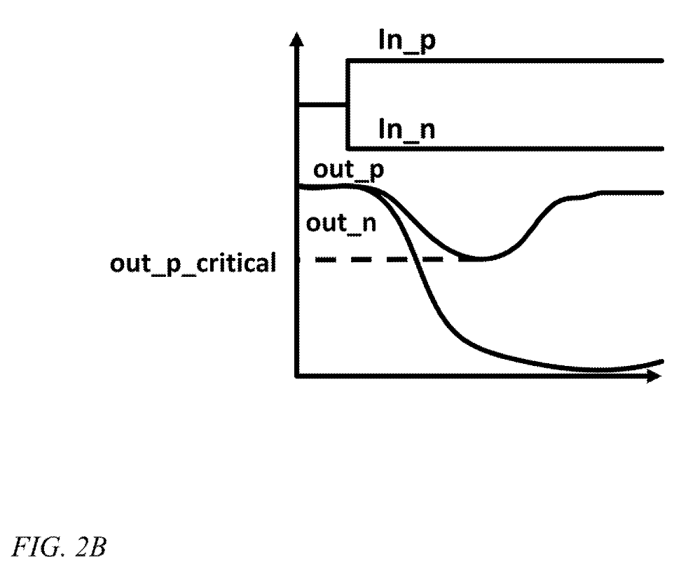

FIGS. 2A and 2B illustrate the operation of the comparator for an input with a modest common-mode voltage. During the half clock cycle when the clock signal is low, each of the resetting transistors 130, 135, 140, 145 is turned on, and each of the resetting transistors 130, 135, 140, 145 pulls up a respective one of the inverter outputs and the comparator outputs. When the clock signal is low the clock enabling transistor 115 is turned off.

When the clock transitions from low to high, transistor N1 will begin to draw a current 205 and transistor N2 will begin to draw a current 210, bringing down the voltages at the outputs out_n and out_p. If In_p is higher than In_n, then the voltage at the output out_n will drop faster than the voltage at the output out_p, as shown in FIG. 2B. When the voltage at the output out_p equals a critical value referred to as “out_p critical”, the current 215 through the transistor P1 is equal to the current 205 through the transistor N1. The voltage at the output out_n then continues to drop, resulting in an increase in the current 215 through the transistor P1, which causes the voltage at the output out_p to increase again, eventually settling at a value of Vdd.

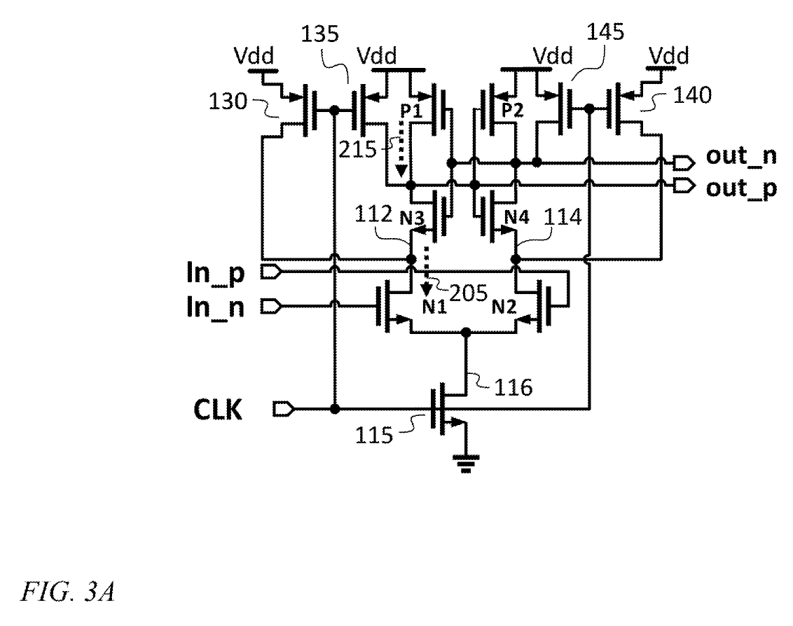

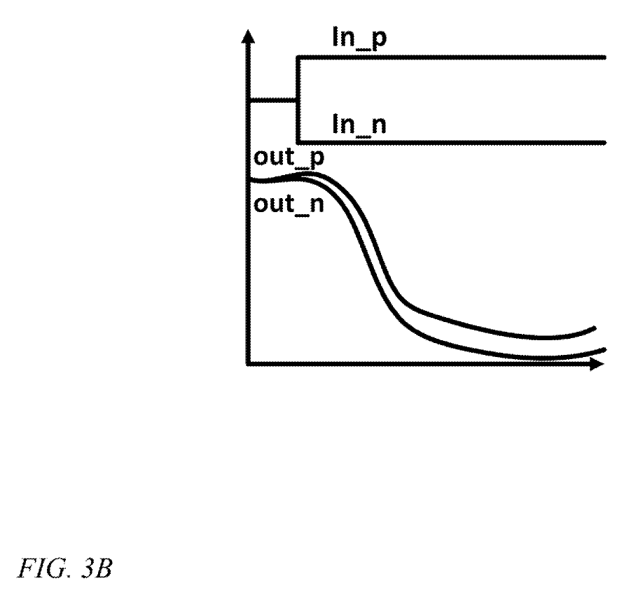

FIGS. 3A and 3B illustrate the operation of the comparator for an input with a high common-mode voltage. With a high common-mode input voltage, the initial current 205, shortly after the rising clock edge, through transistor N1, will be relatively large (e.g., larger than in the case of a modest common-mode input voltage), and the critical voltage, out_p_critical, for which the current 215 through the transistor P1 is equal to the current 205 through the transistor N1, is correspondingly lower (to result in the larger value of the current 215 through the transistor P1). At a sufficiently low value of the voltage at the output out_p, the transistor N3 may be cut off, and instead of increasing to Vdd (as in FIG. 2B), the output node out_p is discharged to ground (as shown in FIG. 3B). In such circumstances, the comparator may therefore fail to produce an output indicating the sign of the voltage difference at the inputs of the comparator.

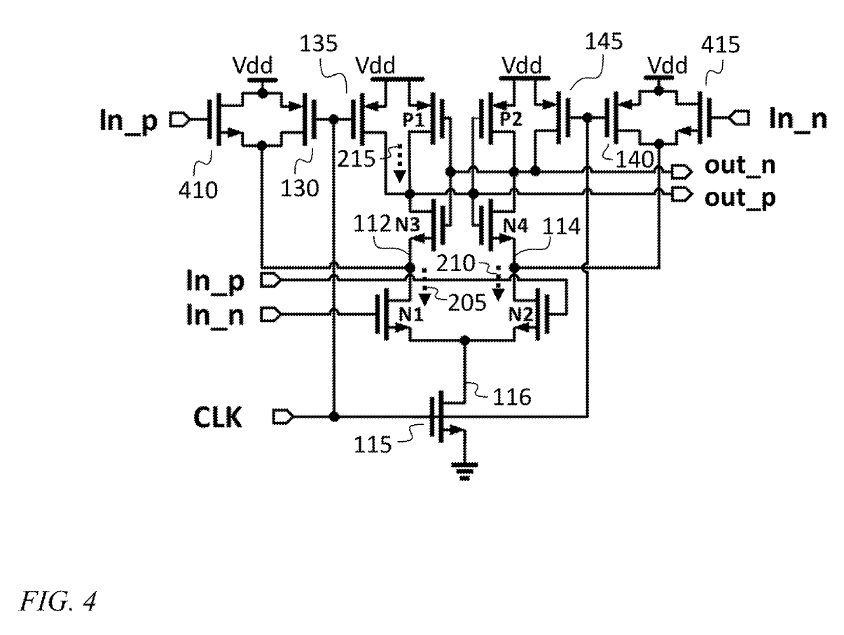

Referring to FIG. 4, the performance of the comparator may be improved by the addition of a first common mode compensation transistor 410 and a second common mode compensation transistor 415. The first common mode compensation transistor 410 is connected between the first voltage source and the first output 112 of the differential pair, and the second common mode compensation transistor 415 is connected between the first voltage source and the second output 114 of the differential pair, as shown. The gate of the first common mode compensation transistor 410 may be connected to the second input In_p of the differential pair 110, and the gate of the second common mode compensation transistor 415 may be connected to the first input In_n of the differential pair 110.

The first common mode compensation transistor 410 may supplement the action of the P1 transistor, and the second common mode compensation transistor 415 may supplement the action of the P2 transistor for high common-mode input voltages. For example, if a large positive voltage is present at both inputs of the comparator, the large positive voltage at the In_n input may result in a large current 205 flowing through the transistor N1, and, at the same time, the large positive voltage at the In_p input (which is connected to the gate of the first common mode compensation transistor 410) may result in the first common mode compensation transistor 410 supplying a significant fraction of that current 205, and a smaller current may therefore flow through the transistor P1. Similarly, the large positive voltage at the In_p input may result in a large current 210 flowing through the transistor N2, and, at the same time, the large positive voltage at the In_n input (which is connected to the gate of the second common mode compensation transistor 415) may result in the second common mode compensation transistor 415 supplying a significant fraction of that current 210, and a smaller current may therefore flow through the transistor P2.

As such, the amount of compensation provided by the common mode compensation transistors 410, 415 is proportional to the common mode component of the input signal. The higher the common mode component is, the greater the extent to which compensation is advantageous, and the more compensation is provided by the common mode compensation transistors 410, 415. An effect of this compensation system may therefore be to keep the strength of the differential pair 110 relatively constant, across a wide range of common-mode input voltages. The common mode compensation transistors 410, 415 may be wired in a push-pull configuration, e.g., with the gate of the first common mode compensation transistor 410 connected to the second input In_p of the differential pair 110 and the gate of the second common mode compensation transistor 415 connected to the first input In_n of the differential pair 110), to increase the gain of the differential pair 110 (i.e., compared to a configuration lacking the common mode compensation transistors 410, 415, or compared to a configuration in which the gate of the first common mode compensation transistor 410 is connected to the first input In_n of the differential pair 110 and the gate of the second common mode compensation transistor 415 is connected to the second input In_p of the differential pair 110).

The size (e.g., the channel width) of the first common mode compensation transistor 410 may be selected to be about the same as the size (e.g., the channel width and length) as the second common mode compensation transistor 415. The size of the common mode compensation transistors 410, 415 may be selected to be comparable in size to (e.g., greater than 0.2 times and less than 5.0 times) the size of the N1 transistor, which may be the same size, or the same size as the size of the N2 transistor. In some embodiments, the size of the common mode compensation transistors 410, 415 is selected by performing simulations, e.g., using a Spectre circuit simulator (available from Cadence) to assess the performance of any particular candidate design, or to optimize the design for a particular figure of merit (e.g., to achieve a target resolution over the largest possible range of common mode voltages, or to achieve the greatest possible resolution at a given common mode voltage). As used herein, a transistor that is “about the same size” as another transistor has a channel width that is within 20% of the channel width of the other transistor (i.e., a channel width that is at least 80% of the channel width of the other transistor and at most 120% of the channel width of the other transistor) and a channel length that is within 20% of the channel length of the other transistor (i.e., a channel length that is at least 80% of the channel length of the other transistor and at most 120% of the channel length of the other transistor).

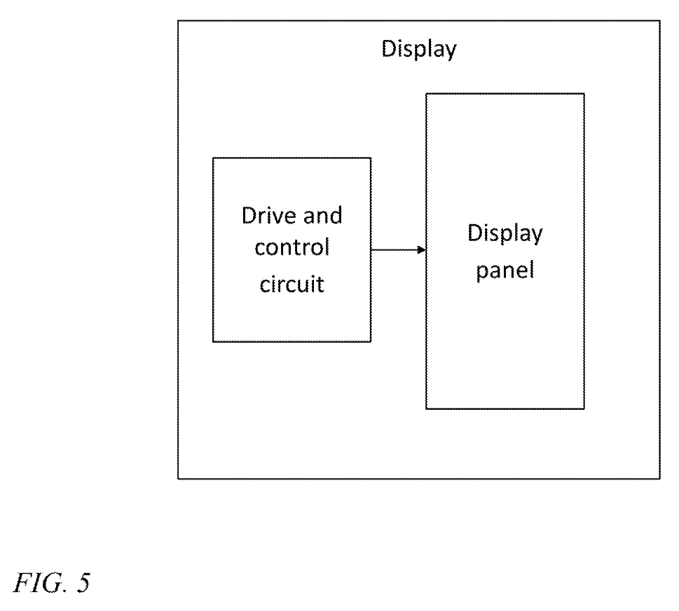

Referring to FIG. 5, some embodiments may be implemented in a display including a display panel and a drive and control circuit. The drive and control circuit may include a plurality of integrated circuits (e.g., a timing controller and one or more driver integrated circuits). One or more of the integrated circuits may include one or more comparators according to some embodiments. It will be understood that some embodiments may be employed in systems that are not displays.

As used herein, the two principal terminals of a transistor (e.g., the source and the drain, for a metal oxide semiconductor field effect transistor (MOSFET), or the collector and the emitter, for a bipolar transistor) may be referred to as the “main” terminals of the transistor, and the terminal used to control the transistor (e.g., the gate, for a MOSFET, or the base, for a bipolar transistor) may be referred to as the “control” terminal of the transistor. As used herein, when the connections to a transistor are described with terminology used for two-terminal devices, it is the connections to the main terminals of the transistor that are described. For example, a transistor that is “connected between” two nodes of a circuit has a first one of the main terminals of the transistor connected to a first one of the two nodes and a second one of the main terminals of the transistor connected to a second one of the two nodes. As another example, when two transistors are said to be connected “in series” (as in the case of a CMOS inverter), a main terminal of one of the two transistors is connected to a main terminal of the other of the two transistors.

As used herein, the terms “high” and “low” are used to refer to two different voltage states, which for the embodiment of FIG. 4 are a first state at or near the positive supply voltage and a second state at or near ground. It will be understood, however, that other voltages may be employed, and that the “high” state need not correspond to a voltage that is higher than the voltage corresponding to the “low” state. For example, a complementary circuit may be fabricated by substituting transistors of opposite polarity transistors for those of FIG. 4 and reversing the supply voltages, in which case the comparator will be in its reset state when the clock signal is nearer the higher of the two supply voltages, which may then nonetheless be referred to as “low” or which may then be referred to as “high”. In such a complementary circuit, currents may flow in directions opposite from those in the embodiment of FIG. 4, and the common mode compensation transistors may, instead of supplying compensating current to the outputs of the differential pair, draw compensating currents from those outputs.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed herein could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that such spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the terms “substantially,” “about,” and similar terms are used as terms of approximation and not as terms of degree, and are intended to account for the inherent deviations in measured or calculated values that would be recognized by those of ordinary skill in the art.

As used herein, the singular forms “a” and “an” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the present invention”. Also, the term “exemplary” is intended to refer to an example or illustration. As used herein, the terms “use,” “using,” and “used” may be considered synonymous with the terms “utilize,” “utilizing,” and “utilized,” respectively.

It will be understood that when an element or layer is referred to as being “on”, “connected to”, “coupled to”, or “adjacent to” another element or layer, it may be directly on, connected to, coupled to, or adjacent to the other element or layer, or one or more intervening elements or layers may be present. In contrast, when an element or layer is referred to as being “directly on”, “directly connected to”, “directly coupled to”, or “immediately adjacent to” another element or layer, there are no intervening elements or layers present.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein.

Although exemplary embodiments of a wide common mode high resolution comparator have been specifically described and illustrated herein, many modifications and variations will be apparent to those skilled in the art. Accordingly, it is to be understood that a wide common mode high resolution comparator constructed according to principles of this invention may be embodied other than as specifically described herein. The invention is also defined in the following claims, and equivalents thereof.

What is claimed is:

1. A comparator, comprising:
a differential pair comprising a first transistor and a second transistor and having:
a first input, connected to a control terminal of the first transistor,
a second input connected to a control terminal of the second transistor,
a first output connected to a main terminal of the first transistor,
a second output connected to a main terminal of the second transistor, and
a common node,
a clock enabling transistor, connected to the common node of the differential pair,
a first inverter having:
an input,
an output,
a first series path terminal, and
a second series path terminal,
a second inverter having:
an input,
an output,
a first series path terminal, and
a second series path terminal,
a first common mode compensation transistor, and
a second common mode compensation transistor,
the input of the first inverter being connected to the output of the second inverter,
the input of the second inverter being connected to the output of the first inverter,
the second series path terminal of the first inverter being connected to the first output of the differential pair,
the second series path terminal of the second inverter being connected to the second output of the differential pair,
the first common mode compensation transistor being connected between a first voltage source and the first output of the differential pair,
the second common mode compensation transistor being connected between the first voltage source and the second output of the differential pair.

2. The comparator of claim 1, wherein a control terminal of the first common mode compensation transistor is connected to the second input of the differential pair.

3. The comparator of claim 2, further comprising a first resetting transistor connected between the first voltage source and the first output of the differential pair, a control terminal of the first resetting transistor being connected to a control terminal of the clock enabling transistor.

4. The comparator of claim 3, further comprising a second resetting transistor connected between the first voltage source and the output of the first inverter, a control terminal of the second resetting transistor being connected to a control terminal of the clock enabling transistor.

5. The comparator of claim 4, further comprising a third resetting transistor connected between the first voltage source and the second output of the differential pair, a control terminal of the third resetting transistor being connected to a control terminal of the clock enabling transistor.

6. The comparator of claim 5, further comprising a fourth resetting transistor connected between the first voltage source and the output of the second inverter, a control terminal of the fourth resetting transistor being connected to a control terminal of the clock enabling transistor.

7. The comparator of claim 1, wherein:
the first inverter comprises two transistors connected in series, between the first voltage source and the first output of the differential pair,
the second inverter comprises two transistors connected in series, between the first voltage source and the second output of the differential pair, and
the clock enabling transistor is connected between the common node of the differential pair and a second voltage source.

8. The comparator of claim 7, wherein:
the first voltage source is at a higher voltage than the second voltage source,
the clock enabling transistor is an n-channel MOSFET,
the first transistor of the differential pair is an n-channel MOSFET,
the second transistor of the differential pair is an n-channel MOSFET,
the first common mode compensation transistor is an n-channel MOSFET, and
the second common mode compensation transistor is an n-channel MOSFET.

9. The comparator of claim 1, wherein the first common mode compensation transistor has a channel width within 20% of a channel width of the first transistor of the differential pair.

10. The comparator of claim 9, wherein the second common mode compensation transistor has a channel width within 20% of a channel width of the first common mode compensation transistor.

11. A comparator, comprising:
two back-to-back inverters,
a differential pair, having two outputs configured to receive respective series currents from, or supply respective series currents to, the back-to-back inverters, and
a first common mode compensation transistor, configured to supply a compensating current to, or draw a compensating current from, a first output of the two outputs of the differential pair.

12. The comparator of claim 11, further comprising a second common mode compensation transistor configured to supply a compensating current to, or draw a compensating current from, a second output of the two outputs of the differential pair.

13. The comparator of claim 12, further comprising a clock-enabling transistor, connected to a clock signal and configured to control a total current through the differential pair.

14. The comparator of claim 13, further comprising a first resetting transistor configured to pull a first output, of the two outputs of the differential pair, high when the clock signal is low.

15. The comparator of claim 14, further comprising a second resetting transistor configured to pull an output of a first inverter, of the two back-to-back inverters, high when the clock signal is low.

16. The comparator of claim 12, wherein the first common mode compensation transistor has a channel width within 20% of a channel width of a first transistor of the differential pair.

17. The comparator of claim 16, wherein the second common mode compensation transistor has a channel width within 20% of a channel width of the first common mode compensation transistor.

18. A display, comprising:
a display panel and a drive and control circuit, the drive and control circuit comprising a plurality of integrated circuits, an integrated circuit of the plurality of integrated circuits comprising a comparator, the comparator comprising:
a differential pair comprising a first transistor and a second transistor and having:
a first input, connected to a control terminal of the first transistor,
a second input connected to a control terminal of the second transistor,
a first output connected to a main terminal of the first transistor,
a second output connected to a main terminal of the second transistor, and
a common node,
a clock enabling transistor, connected to the common node of the differential pair,
a first inverter having:
an input,
an output,
a first series path terminal, and
a second series path terminal,
a second inverter having:
an input,
an output,
a first series path terminal, and
a second series path terminal,
a first common mode compensation transistor, and
a second common mode compensation transistor,
the input of the first inverter being connected to the output of the second inverter,
the input of the second inverter being connected to the output of the first inverter,
the second series path terminal of the first inverter being connected to the first output of the differential pair,
the second series path terminal of the second inverter being connected to the second output of the differential pair,
the first common mode compensation transistor being connected between a first voltage source and the first output of the differential pair,
the second common mode compensation transistor being connected between the first voltage source and the second output of the differential pair.

19. The comparator of claim 18, wherein a control terminal of the first common mode compensation transistor is connected to the second input of the differential pair.

20. The comparator of claim 19, wherein a control terminal of the second common mode compensation transistor is connected to the first input of the differential pair.
